(19) United States
(12) Patent Application Publication
(10) Pub. No.: US 2006/0121721 A1
(43) Pub. Date: Jun. 8, 2006

(54) Methods for forming dual damascene wiring using porogen containing sacrificial via filler material

(75) Inventors: Kyoung Woo Lee, Fishkill, NY (US); Hong Jae Shin, Seoul (KR); Jae Hak Kim, Fishkill, NY (US)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/223,310

(22) Filed: Sep. 9, 2005

(30) Foreign Application Priority Data
Dec. 8, 2004 (KR) 10-2004-0103088

(51) Int. Cl. H01L 21/4763

(52) U.S. Cl. 438/618

(57) ABSTRACT

Methods for fabricating dual damascene interconnect structures are provided in which a sacrificial material containing porogen (a pore forming agent) is used for filling via holes in an interlayer dielectric layer such that the sacrificial material can be transformed to porous material that can be quickly and efficiently removed from the via holes without damaging or removing the interlayer dielectric layer.

### CROSS-REFERENCE TO RELATED APPLICATION

This application claims priority to Korean Patent Application No. 10-2004-0103088, filed on Dec. 8, 2004, which is incorporated herein by reference.

### TECHNICAL FIELD

The present invention relates generally to methods for fabricating dual damascene interconnect structures and, in particular, to dual damascene methods in which a sacrificial material containing porogen (a pore forming agent) is used for filling via holes in an interlayer dielectric layer such that the sacrificial material can be transformed to porous material that can be readily removed from the via holes without damaging or removing the interlayer dielectric layer.

### BACKGROUND

Due to continued technological innovations in the field of semiconductor fabrication which allow integrated circuits to be designed according to smaller design rules (DR), semiconductor devices are becoming more highly integrated. Typically, highly integrated circuits are designed using multi-layered metal interconnection structures in which the wires/interconnects are formed from different metals layers of an integrated circuit. Generally, multi-layered metal interconnection lines are formed of a metallic material, such as copper (Cu), having low resistivity and high reliability to yield improved performance. However, copper is difficult to pattern using a conventional photolithography/etching techniques, especially when the copper wires are formed according to relatively small design rules. Accordingly, dual damascene methods have been developed to enable formation of highly integrated copper metal interconnect structures.

In general, dual damascene methods are used to form upper metal lines that are electrically connected to lower metal lines with conductive vias. For example, a conventional dual damascene method generally includes process steps such as forming an interlayer dielectric (ILD) layer over a lower metal line on a semiconductor substrate, etching a via hole in the ILD layer, which is aligned to a predetermined region of the lower metal line, filling the via hole with a sacrificial material and forming a trench region in the ILD layer, which is aligned to the filled via hole. As is known in the art, the use of via-filling sacrificial material allows formation of trench and via contact regions in the ILD layer having excellent etch profiles. Moreover, the sacrificial via filling material protects the lower metal line and sidewall surfaces of the ILD layer in the via contact hole from damage or contamination due to etching atmospheres during trench formation and/or due to subsequent ashing or cleaning steps for removing photoresist material.

After the trench regions are formed in the ILD layer, the sacrificial material remaining in the via hole is etched away using etch chemistries that are selected to provide high etch selectivity of the sacrificial material with respect to the dielectric material of the ILD layer. Thereafter, the upper metal lines and via contacts are formed by filling the via and the trench regions in the ILD layer with conductive material (such as copper).

Although dual damascene methods allow formation of metal interconnect structures that yield improved performance, such methods become more problematic with decreasing design rules. For instance, with decreasing design rules, parasitic resistance and capacitance that exists between adjacent metal wiring layers in a lateral direction or in a vertical direction may affect the performance of the semiconductor devices. Indeed, parasitic capacitance and resistance results in capacitive coupling and cross talk between adjacent metal lines, which decreases the performance. Further, the parasitic resistance and capacitance components result in increased signal leakage and increased power consumption of the semiconductor device.

To reduce parasitic capacitance, dielectric materials having a low dielectric constant, k, are used to form ILD layers. Although the use of low-k dielectric materials provides improved performance, ILD layers formed with such low-k dielectric materials are more susceptible to etching damage. For instance, in the conventional process as described above, an ILD layer formed of a low-k dielectric material can be damaged (contaminated and/or undesirably etched) during removal of the via-filling sacrificial material. Thus, it would be advantageous to provide efficient methods for removing residual sacrificial material without resulting in damage to ILD layers, especially ILD layers formed with low-k dielectric materials.

U.S. Pat. No. 6,833,320 to Meagley et al. discloses a dual damascene process which employs a thermally decomposable sacrificial via-filling material that can be removed from a via hole by thermal decomposition without damaging or removing the ILD layer material. More specifically, Meagley discloses a dual damascene method which generally includes forming a via contact hole in a ILD layer on a semiconductor substrate, depositing a thermally decomposable sacrificial material in the via contact hole, etching the ILD layer and thermally decomposable sacrificial material to form a trench region, and then heating the semiconductor substrate to remove any remaining thermally decomposable sacrificial material within the via contact hole.

Meagley discloses that the thermally decomposable sacrificial material is a material that may be thermally decomposed and evaporated at an acceptable temperature, preferably less than 450 degrees C., in a reducing atmosphere, so that the thermally decomposable sacrificial material can be removed without damaging dielectric material with a low dielectric constant. The thermally decomposable material may be a combination of inorganic and organic materials such as a combination of silicon-containing and carbonaceous materials (e.g., a hydrocarbon-siloxane polymer hybrid material). Meagley further discloses that a chemical cleaning process may be applied to remove residual/remaining thermally decomposable sacrificial material from the via contact hole after heating the semiconductor substrate to remove thermally decomposable sacrificial material from the via contact hole.

Although the methods disclosed by Meagley may help to minimize damage to an ILD layer formed of low-k dielectric material, the types of thermally decomposable sacrificial materials disclosed by Meagley may actually result in some damage to the ILD layer during removal of the sacrificial material. More specifically, during a thermal process in which the substrate is heated to thermally decompose and evaporate the thermally decomposable sacrificial material, the types of thermally decomposable materials disclosed by Meagley tend to lose structural integrity and shrink when thermally decomposed. The shrinkage of the sacrificial material during thermal decomposition results in significant stresses and strains on the ILD material due to the contact forces applied to the ILD material as the sacrificial material loses structural integrity and shrinks during thermal decomposition.

Moreover, the types of thermally decomposable materials disclosed by Meagley tend to form hard residual materials as a result of thermal processes and thermal decomposition of the sacrificial materials. As noted above, Meagley discloses a method in which a chemical cleaning process can be applied to remove residual/remaining thermally decomposed sacrificial material in a contact via hole. However, the hard residual, thermally decomposed material can be difficult to remove during a subsequent chemical cleaning process, and the type of etch chemistries and/or etching time needed to remove such residual thermally decomposed sacrificial material from the via hole can actually result in damage to the low-k dielectric material forming the ILD layer.

### SUMMARY OF THE INVENTION

In general, exemplary embodiments of the invention include methods for fabricating dual damascene interconnect structures and, in particular, to dual damascene methods in which a sacrificial material containing porogen (a pore forming agent) is used for filling via holes in an ILD (interlayer dielectric) layer such that the sacrificial material can be transformed to a porous sacrificial material which can be readily removed from the via holes without damaging or removing the interlayer dielectric layer.

More specifically, the sacrificial material is formed with a porogen/matrix material composition that enables the porogen containing sacrificial material to maintain its structure when converted to a porous sacrificial material. In this manner, no stress is applied to surrounding structures due to shrinkage of the sacrificial material when the porogen is removed, thus preventing damage, cracking or breaking of the ILD layer.

Moreover, the formation of pores in the base (matrix) material of the sacrificial material results in an effective increase in the surface area of the sacrificial material that can be contacted by an etch solution/gas, thereby enabling the porous sacrificial material to be more easily and quickly removed and, thus significantly minimizing etch damage to the ILD layer.

In one exemplary embodiment, a method for forming an interconnection structure includes forming an etch stop layer on a semiconductor substrate that has a lower conductive layer formed thereon, forming an ILD (interlayer dielectric) layer on the etch stop layer, forming a via hole through the ILD layer to expose a portion of the etch stop layer, wherein the via hole is aligned with a portion of the lower conductive layer, filling the via hole with a sacrificial material comprising a combination of a base (matrix) material and a porogen material, forming a trench in the ILD layer aligned with the via hole, removing the porogen material from the sacrificial material to convert the sacrificial material to a porous sacrificial material comprising the base (matrix) material with pores formed therein, removing the porous sacrificial material in the via hole to expose a portion of the etch stop layer, removing the exposed portion of the etch stop layer, and forming an interconnection by filling the trench and via hole with a conductive material.

In general, the sacrificial material may be formed of a combination of an organic or inorganic base (matrix) material and a porogen material, wherein the porogen may be removed from the matrix material to create pores or voids in the matrix material while maintaining the structural integrity of the matrix material. In one exemplary embodiment, the base (matrix) material may be an organic SOP (spin-on-polymer) material such as a poly arylene ether-based material, a polymetamethylacrylate-based material, or a vinylethermetacrylate-based material. In another exemplary embodiment, the base (matrix) material may be an inorganic SOG (spin-on-glass) material such as an HSQ (hydrogenSilsesQuioxane)-based material or an MSQ (MethylSilsesQuioxane)-based material.

In one exemplary embodiment, the porogen can be removed from the sacrificial material by heating the sacrificial material to a temperature above a boiling point of the porogen material to dissolve the porogen material from the base material. The heating may be performed in a vacuum or nitrogen environment. In one exemplary embodiment, the porogen material is selected to have a boiling point in a range of about 150 degrees C. to about less than 400 degrees C.

In another exemplary embodiment, the porogen material can be removed from the sacrificial material by applying UV radiation to the sacrificial material while heating the sacrificial material.

In yet another exemplary embodiment, the porogen material can be removed by applying a plasma treatment to dissolve the porogen material from the base material. The plasma treatment can be performed using a nitrogen-based plasma or hydrogen-based plasma treatment process.

In one exemplary embodiment, the porous sacrificial material can be removed using a wet strip process or an ashing process. For example, when the porous sacrificial material comprises an inorganic base material and the ILD layer is formed of an organic material, the porous sacrificial material can be removed using a wet strip process with an etch chemistry having an etching selectively with respect to the porous material. When the porous sacrificial material is formed of an organic base material and the ILD layer is formed of an inorganic material, the porous sacrificial material can be removed using a plasma ashing or H2 based plasma ashing process or a wet etch process. In all instances, the pores dispersed throughout the porous sacrificial material provides more surface area for etching, enabling quick removal of the porous material from the via contact hole, for instance.

These and other exemplary embodiments, aspects, features and advantages of the present invention will become apparent from the following detailed description of exemplary embodiments, which is to be read in connection with the accompanying drawings.

### BRIEF DESCRIPTION OF THE DRAWINGS

FIGS. 1 through 9 are cross-sectional views that illustrate a method for forming a metal wiring layer of a semiconductor device according to exemplary embodiments of the invention.

FIGS. 10 through 18 are cross-sectional views that illustrate a method for forming a metal wiring layer of a semiconductor device according to another exemplary embodiment of the invention.

### DETAILED DESCRIPTION OF EXEMPLARY EMBODIMENTS

Exemplary embodiments of the invention will now be described more fully with reference to the accompanying drawings in which it is to be understood that the thickness and dimensions of the layers and regions are exaggerated for clarity. It is to be further understood that when a layer is described as being “on” or “over” another layer or substrate, such layer may be directly on the other layer or substrate, or intervening layers may also be present. Moreover, similar reference numerals used throughout the drawings denote elements having the same or similar functions.

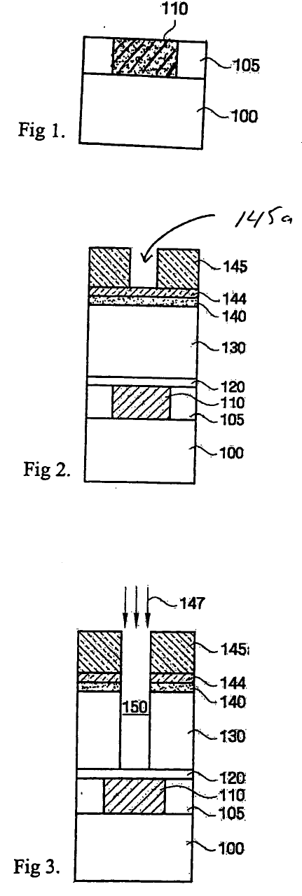

FIGS. 1 through 9 are schematic cross-sectional views illustrating a method for forming a metal wiring layer of a semiconductor device according to an exemplary embodiment of the present invention. More specifically, FIGS. 1 through 9 illustrates a dual damascene method in which a sacrificial material containing porogen (a pore forming agent) is used for filling via holes in an interlayer dielectric layer such that the sacrificial material can be transformed to porous material that can be readily removed from the via holes without damaging or removing the interlayer dielectric layer.

Referring to FIG. 1, a semiconductor substrate (100) is shown having a first ILD (inter layer dielectric) layer (105) (or insulation layer) and lower interconnection line (110) formed thereon. The substrate (100) may be any semiconductor device such as a silicon substrate having integrated circuit devices formed therein. In one exemplary embodiment, the first ILD layer (105) is formed on the semiconductor substrate (100) and the lower interconnection line (110) is formed in the ILD layer (105) using a damascene technique. The lower interconnection line (110) may be formed of any suitable material typically used to form conductive layers for integrated circuits. For instance, the lower interconnection line may comprise a metallic material such as copper, a copper alloy, aluminum, aluminum alloy, tungsten or other suitable metals or conductive materials.

Referring to FIG. 2, an etch stop layer (120) (or barrier layer), a second ILD layer (130) and a capping layer (140) (or hard mask layer) are sequentially formed on the structure of FIG. 1. The etch stop layer (120) acts as an etch stop layer for a subsequent via etch process (described below) to prevent exposure of the lower interconnection line (110). The etch stop layer (120) also acts as a diffusion barrier layer to prevent/reduce diffusion of the metallic material into the ILD layer (130). The etch stop layer (120) is made as thin as possible to maintain an overall low dielectric characteristic of the insulation stack (120 and 130), while providing a sufficient diffusion barrier. In one exemplary embodiment, the etch stop layer (120) is formed of an insulating material having a thickness of about 300 to about 500 angstroms, and having a high etching selectivity with respect to the ILD layer (130). For example, the etch stop layer (120) may be formed of SiC, SiN, SiCN, SiCO or SiCON, for example, and formed using known techniques.

In one exemplary embodiment, the ILD layer (130) is preferably formed of a low-k dielectric material with k less than about 4.2. The ILD layer (130) may be formed of an organic polymer material or an inorganic material. More specifically, the ILD layer (130) may be formed of a silicon oxide layer doped with carbon, fluorine or hydrogen atoms, e.g., a silicon oxycarbide (SiOC) layer, a SiOCH layer, a fluoro-silses-quioxane layer (FSQ) layer, a hydro-silses-quioxane (HSQ) layer or a methyl-silses-quioxane (MSQ) layer. Whatever materials are used for the etch stop layer (120) and ILD layer (130), the ILD layer (130) is preferably formed of a material having a high etching selectivity with respect to the stopper layer (120) and having a low dielectric constant.

The capping layer (140) (or hard mask layer) may be formed to protect the ILD layer (130) from being damaged during plasma processes and to act as a buffer layer for a subsequent CMP process. The capping layer (140) is formed with a material having a high etching selectivity with respect to the ILD layer (130). For example, the hard mask layer (140) may be formed of: (i) an insulating nitride layer, such as a silicon nitride layer (SiN), a silicon carbonitride layer (SiCN) or a boron nitride layer (BN); (ii) an insulating carbide layer, such as a silicon carbide layer (SiC); (iii) a metal nitride layer, such as a tantalum nitride (TaN) layer, a titanium nitride (TiN) layer, a tungsten nitride (WN) layer or an aluminum nitride (AlN) layer; (iv) a metal oxide layer, such as an aluminum oxide (AL₂O₃) layer, a tantalum oxide (TaO) layer or a titanium oxide (TiO) layer; or (v) a silicon layer such SiO2, or other materials such as SiOF and SiON, for example.

A next step in the exemplary process includes forming a via hole in the ILD layer (130). For example, as further depicted in FIG. 2, an ARL (anti-reflection layer) (144) is formed on the capping layer (140) and a photoresist pattern (145) is formed having an opening (145a) through which a portion of the surface of the ARL (144) is exposed. The opening (145a) is aligned to the lower interconnect line (110) and defines a pattern for forming a via hole (150), as depicted in FIG. 3.

In particular, referring to FIG. 3, one or more separate etch processes (147) are applied to the structure of FIG. 2 using the photoresist pattern (145) as an etching mask, to thereby sequentially etching the ARL (144), the capping layer (140) and the ILD layer (130) to form the via hole (150) down to the etch stop layer (120). The ILD layer (130) may be etched using any conventional etch process, such as an anisotropic dry oxide etch process, which is suitable to etch the material of the ILD layer (130).

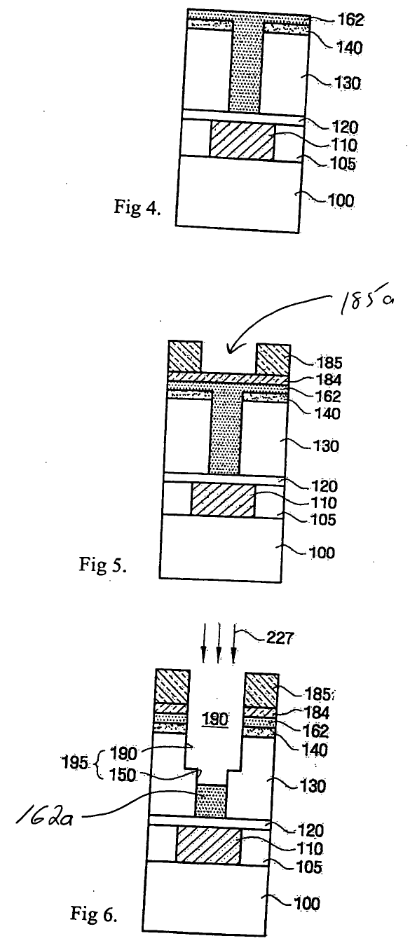

Referring to FIG. 4, after the via hole (150) is formed, the photoresist pattern (145) and ARL (144) are removed using, e.g., an ashing process (O2 or H2 plasma) and organic stripper. Thereafter, a layer of sacrificial material (162) is deposited to fill the via hole (150). In accordance with an exemplary embodiment of the invention, the sacrificial material (162) is formed of a material comprising a combination of a base (matrix) material and a porogen (pore-generating) material. More specifically, the sacrificial material (162) is preferably formed of a combination of an organic or inorganic base (matrix) material and a porogen material which can be removed from the matrix material to create pores or voids in the matrix material while maintaining the structure integrity of the matrix material. The type of porogen material that may be implemented include any compounds well known in the art, including, but not limited to, Tetradecane, Bicycloheptadiene, or Butane and Alpha-Terpinene, wherein the porogen material comprises about 10˜40% of the total porogen/matrix material of the sacrificial material.

For example, the sacrificial material (162) may be formed of a combination of a porogen material and an organic spin-on-polymer (SOP) base (matrix) material such as a polyaryleneether, polymetamethylacrylate, or a vinylether metacrylate based material. In another exemplary embodiment of the invention, the sacrificial material (162) may be formed of a combination of a porogen material and an inorganic spin-on-glass (SOG) base (matrix) material such as an HSQ (HydrogenSilsesQuioxane) based material or an MSQ (MethylSisesQuioxane) based material.

The porogen material may be any suitable material (a solid, liquid, or gaseous material) that is removable from the base matrix material to create pores or voids in the cured base matrix material. Many types of materials, such as polymeric materials, may be used as a porogen, and the type of porogen used will depend on the compatibility of the porogen with the matrix material. For example, the porogen and base material are preferably selected such that the porogen material can thermally degrade at temperatures below the thermal stability temperature of the matrix material. In addition, the porogen and base materials are preferably selected such that while the sacrificial material is cured, the phase separation between the porogen and matrix material is such that the porogen aggregates and forms masses of porogen material, which are substantially equally dispersed throughout the matrix material.

In addition to exemplary properties discussed above, the sacrificial material (162) is formed of materials that provide uniform gap filling characteristics to minimize formation of voids in the sacrificial material (162). Moreover, the sacrificial material (162) is preferably selected to have dry etch properties that are similar to the dry etch properties of the dielectric material that forms the ILD layer (130). For example, the sacrificial material (162) preferably has a dry etch rate that is slightly faster than the dry etch rate of the ILD layer (130) for a given dry etch chemistry. As explained below, this ensures that a sufficient amount of sacrificial material remains in the via hole (150) during formation of the trench region. Moreover, as will be explained below, the base (matrix) material of the sacrificial material (162) is selected such that after removal of the porogen material from the sacrificial material, the remaining base (porous matrix) material has a wet etch rate that is significantly faster than the wet etch rate of the ILD layer (130). As explained below, this enables removal of the remaining porous sacrificial material in the via hole (150) after the trench regions is formed. Whether an SOP or SOG sacrificial material is used will depend on the material that forms the ILD layer (130) and the desired etch selectivity between the ILD layer (130) and sacrificial material (162) for the given etch chemistries.

In general, the layer of sacrificial material (162) may be formed by forming a solution of matrix material, porogen and a solvent, and applying the sacrificial material solution to the substrate by a method such as spin coating. To cure the sacrificial material, the solvent can be removed by evaporation and/or heating, resulting in a sacrificial material (162) having the porogen material dispersed in the matrix material. Further thermal processing may be applied to separate the porogen from the matrix material and form masses of porogen material dispersed throughout the matrix material and fully cure the matrix material. As discussed below, further heat treatment is applied to remove the porogen material from the matrix material to form a porous matrix material.

When forming the sacrificial material solution, the amount of matrix material relative to the amount of porogen may be adjusted to obtain a desired porosity. For example, in one exemplary embodiment, the sacrificial material (162) comprises porogen material in an amount of about 1 wt % to about 70 wt % of a total weight of the sacrificial material (162).

A next step in the exemplary process is forming a trench region in the ILD layer (130). Referring to FIG. 5, the exemplary process commences with forming a second ARL (anti-reflection layer) (184) on the layer of sacrificial material (162) and forming a second photoresist pattern (185) having an opening (185a) through which a portion of the surface of the second ARL (184) is exposed. The opening (185a) is formed to align to the via hole (150), and the opening (185a) defines an etch pattern for forming a trench in the ILD layer (130), as explained hereafter.

Referring to FIG. 6, an etch process (227) is performed to form a trench (190) by sequentially etching the ARL (184), the sacrificial material (162) and the ILD layer (130) using the photoresist pattern (185) as an etching mask. In one exemplary method, the etching (227) is performed using a dry etch process with an etch chemistry that is suitable for etching the types of materials forming the different layers. As noted above, the dry etch chemistry for etching the trench (190) is selected such that the sacrificial material (162) is etched at, e.g., a slightly faster rate than the IDL layer (130) to avoid formation of defects. In particular, the etching is performed such that the etch rate between the sacrificial material (162) and the ILD (130) is substantially the same or lower than 10:1. The etching process is applied for a time sufficient to form a trench (190) having a desired trench depth below the top surface of the ILD layer (130). During the dry etching process, the sacrificial material (162a) remaining in the via hole (150) is recessed below the bottom of the trench (190) such that a non-filled region (195) is formed that comprises the trench (190) and a portion of the via hole (150).

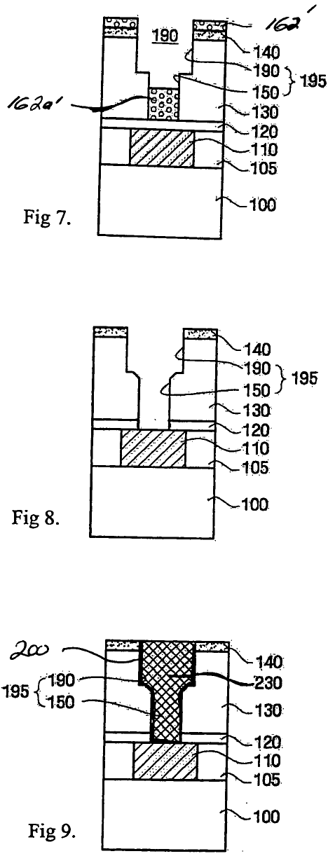

Referring to FIG. 7, the second photoresist pattern (185) and ARL (184) are removed using an ashing process, for example, or using any etch process that is selective to the photoresist, but does not remove the sacrificial material (162) or the material of the ILD layer (130). Thereafter, a process is performed to remove the porogen material from the sacrificial material (162) to convert the remaining sacrificial material (162, 162a) to a porous matrix material (162′, 162a′). In particular, the sacrificial material is transformed to a porous matrix material by decomposing the pockets/regions of porogen material, which are dispersed throughout the base matrix material, to thereby create pores or voids in the matrix material. In this manner, the sacrificial material is converted to a porous matrix material, wherein the matrix is a solid phase surrounding dispersed voids/pores.

In one exemplary embodiment of the invention, the porogen material can be removed from the sacrificial material by heating the sacrificial material to a temperature above a boiling point of the porogen material to dissolve the porogen material from the base material. The heating is performed for about 1 minute to about 2 hours. The heating is performed in a vacuum, nitrogen or another inert ambient environment. In one exemplary embodiment, the boiling point of the porogen material is in a range of about 150 degrees C. to about less than 400 degrees C. In another embodiment, UV radiation can be applied to the sacrificial material while heating the sacrificial material to assist in removal of the porogen material. In another exemplary embodiment of the invention, removing the porogen material may be performed using a plasma treatment process to dissolve the porogen material from the base material. The plasma treatment is performed using a nitrogen-based plasma or hydrogen-based plasma.

Advantageously, the porous sacrificial material (162′, 162a′) is formed such that the matrix material maintains its structural integrity (the matrix base material maintains its structure), but is porous. Therefore, when the porogen containing sacrificial material (162) is converted to porous sacrificial material (162′), no stress is applied to the ILD layer (e.g., stress due to shrinkage as in the conventional process), thus preventing damage, cracking or breaking of the ILD layer. Moreover, the porosity of the remaining matrix material results in an effective increase in the surface area of the sacrificial material, thereby enabling the porous sacrificial material (160, 162a) in the via hole (150) and on the hard mask layer (140) to be more easily and quickly removed and, thus significantly minimizing damage to the ILD layer when removing such porous material.

In FIG. 7, the remaining porous sacrificial material (162′, 162a′) can be readily removed one of various methods. For example, when the porous sacrificial material (162′, 162a′) comprises an inorganic base material and the ILD layer (130) is formed of an organic material, the porous sacrificial material (162′, 162a′) can be removed using a wet strip process. When the sacrificial material (162) is an inorganic SOG material, the sacrificial material that is formed on the hard mask layer (140), as well as the sacrificial material (162a) remaining in the via hole (150), is removed using a wet etch process, after the photoresist pattern (185) and ARL (184) are removed. As noted above, a wet etch chemistry (e.g., such as an HF solution) is selected such that the sacrificial material is selectively etched at a significantly faster rate that the ILD layer (130). For example, if the sacrificial material (162) is formed of a SOG layer (such as an HSQ layer) and the ILD layer (130) is formed of SiOC, the sacrificial material (162) will be etched significantly faster in an HF solution than the ILD layer (130). In short, the wet chemistry is selected to provide high selectivity between the sacrificial material (162) and the material of the ILD layer (130).

Furthermore, due to the existence of the pores in the base material, the wet etch process results in removing the sacrificial material 2-4 times faster than removal of the same, non-porous base material because the wet etch solution can readily penetrate into the porous base material. In other words, the existence of the pores in the base material effectively increases the surface area of the sacrificial material to which the etch solution can be applied. The increased etch rate of the porous sacrificial material allows fast and efficient removal of the porous sacrificial material to minimize or otherwise prevent damage to the ILD layer (130).

When the porous sacrificial material (162′, 162a′) is formed of an organic base material and the ILD layer (130) is formed of an inorganic material, the porous sacrificial material (162′, 162a′) can be removed using a plasma ashing or H2 based plasma ashing process or a wet etch process. When the sacrificial material is formed of an organic material, the sacrificial material does not have be preserved during ashing. In such instance, the sacrificial material and photoresist can be removed simultaneously, but more effectively by generating pores in the sacrificial layer. In one exemplary embodiment, the porogen material in sacrificial layer can be removed as follows. First, an anneal process and/or UV process is performed prior to ashing. Next, an ashing process is performed, which comprises a plasma treatment process as well as thermal process.

After removing the porous sacrificial material (162′, 162a′), the next step of the exemplary method includes removing the portion of the etch stop layer (120) that is exposed on the bottom of the via hole (150) to expose the lower conductive layer (110). This etch process may be performed using known techniques to selectively etch the material forming the etch stop layer (120) without etching the ILD layer (130). The resulting structure is depicted in the exemplary diagram of FIG. 8.

Thereafter, referring to FIG. 9, an upper metal interconnection (230) (dual damascene interconnection) is formed by filling the trench (190) and via hole (150) with conductive material such as copper. More specifically, in one exemplary embodiment, a method of forming the upper interconnection structure (230) includes forming a conformal barrier layer (200) on the sidewalls of the trench (190) and via hole (150). In one exemplary embodiment, the barrier layer (200) may be formed using a sputter deposition process to form a barrier layer of thickness of about 50 angstroms to about 500 angstroms with a material such as TiN or TaN, for example. Thereafter, a layer of conductive material is deposited over the conformal barrier layer (200) to fill the via hole (150) and trench (190) with the conductive material, and then a planarization (e.g., CMP) process is performed to planarize the top surface of the structure down to the hard mask layer (140), thus completing formation of a metal wiring layer having a dual damascene structure (230).

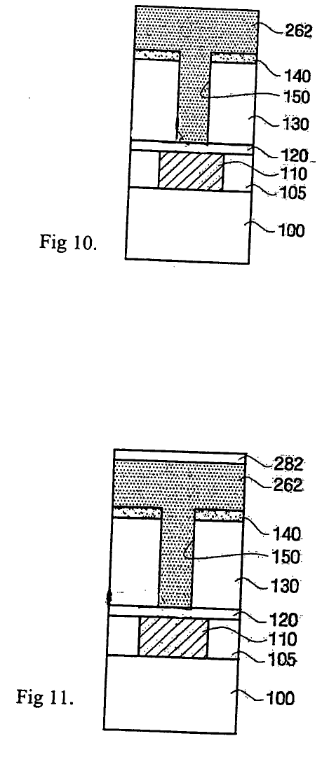

The exemplary methods described above with reference to FIGS. 1 through 9 are referred to as a VFDD (via first dual damascene process) that are performed using a SLR (single layered resist) process. With the exemplary VFDD SLR process, the base (matrix) material of the sacrificial material (162) can be organic or an inorganic material that is combined with porogen. In another exemplary embodiment of the invention, a VFDD MLR (multi-layered resist process) will be described with reference to the exemplary diagrams of FIGS. 10˜18. With the exemplary method, the sacrificial material is formed of an organic base (matrix) material to act as a photoresist during an etch process. The exemplary method of FIGS. 10-18 will now be described beginning with reference to FIG. 10, but it is to be understood that the exemplary method steps discussed above with reference to FIGS. 1, 2 and 3 are processing steps that may precede the processing steps beginning with reference to FIG. 10, and will not be repeated.

Referring to FIG. 10, after formation of the via hole (150) (e.g., FIG. 3), a layer of sacrificial material (262) is deposited to fill the via hole (150) sacrificial material (262). As described above, the sacrificial material (262) comprises a base (matrix) material combined with a porogen material, and provides uniform gap filling characteristics to minimize formation of voids in the sacrificial material (262). In the exemplary embodiment, the base material of the sacrificial material (262) is formed of an organic SOP (spin-on-polymer) material such as such as a polyaryleneether, polymetamethylacrylate, or a vinylether metacrylate based material. As with the exemplary embodiments discussed above, the sacrificial material (262) is preferably selected to have given dry and wet etch properties with respect to the dielectric material that forms the ILD layer (130) to achieve the desired etching selectivities for etching the trench region and removing residual sacrificial material in subsequent processing steps as discussed below.

Comparing the exemplary diagram of FIG. 10 and FIG. 4, it is noted that the layer of sacrificial material (262) in FIG. 10 is formed thicker than the sacrificial material (162) in FIG. 4. The sacrificial material (262) is formed sufficiently thick in this exemplary embodiment because, as will be explained below (FIG. 15), the layer of sacrificial material (262) is used as an etch mask during a subsequent etch process.

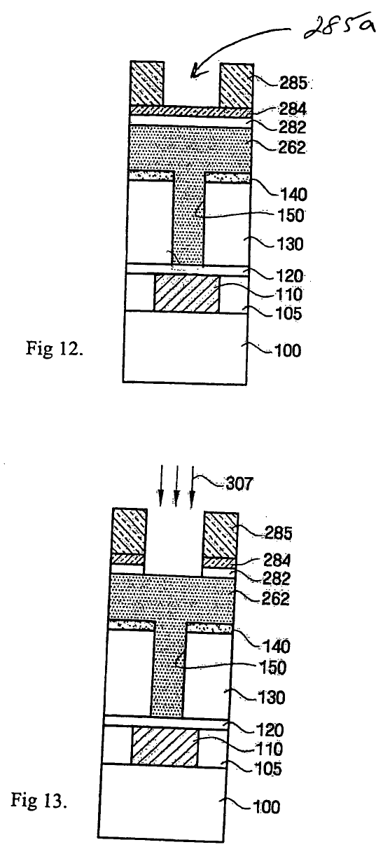

Referring to FIG. 12, a hard mask layer (282) is formed on the layer of sacrificial material (262). The hard mask layer (282) may be a silicon oxide layer, a silicon nitride layer, a silicon carbide layer, SiON, SiCN, SiOCN, Ta, TaN, Ti, TiN, Al2O3, BQ, HSQ. The material forming the hard mask layer (282) is selected to have a high etching selectivity with respect to the sacrificial material (262).

Referring to FIG. 12, an ARL (anti-reflection layer) (284) is formed on the hard mask layer (282) and a photoresist pattern (285) is formed having an opening (285a) through which a portion of the surface of the ARL (284) is exposed. The opening (285a) is formed to align to the via hole (150), and the opening (285a) defines an etch pattern for forming a trench region in the ILD layer (130).

Referring to FIG. 13, one or more etch processes (307) are performed using the photoresist pattern (285) as an etch mask to sequentially etch the portions of the ARL (284) and hard mask layer (282) exposed by the opening (285a), to thereby pattern the hard mask layer (282). In one exemplary embodiment, the etch process (307) is performed such that the layers (284) and (282) are etched using a single etch process. In another exemplary embodiment, the etch process (307) is performed using separate etch steps for each of the layers (284) and (282) where, for instance, the ARL (284) is an organic material and the hard mask layer (282) is an inorganic material.

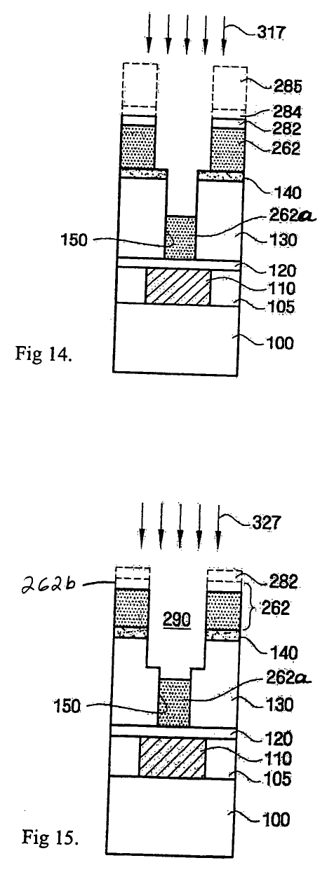

Referring to FIG. 14, a second etch process (317) is performed for a given period of time to etch the sacrificial material (262) exposed by opening (285a). The second etch process (317) is performed with an etch chemistry that causes the photoresist pattern (285) and ARL (284) to be removed while etching the sacrificial material (262). In one embodiment, the second etch process (317) is performed using a dry etch process with etching gases such as O2/N2/CFx or N2/H2/CFx. As depicted in FIG. 14, the second etch process (317) is performed to etch the sacrificial material (262a) down to a level in the via hole (150) which is the same or lower than a desired trench level. With the exemplary etch process (317), the patterned hard mask layer (282) is exposed.

Referring to FIG. 15, a third etch process (327) is performed using the patterned hard mask layer (282) and sacrificial material layer (262) as an etch mask to etch the exposed portions of the capping layer (140) and ILD layer (130) to form a trench (290). In the exemplary embodiment, the exposed portions of the capping layer (140) and ILD layer (130) are etched to form the trench (290) to a desired level below the top surface of the ILD layer (130).

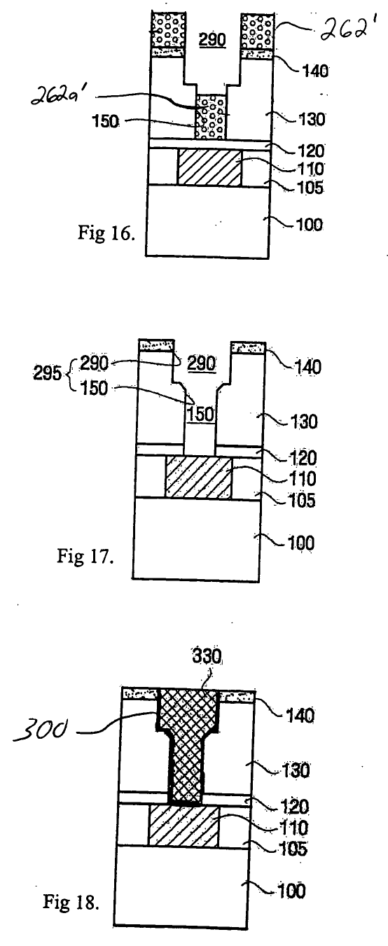

In one exemplary method, the etching (327) is performed using an etch chemistry that is highly selective to hard mask layer (282), the capping layer (140) and ILD layer (130) with respect to the sacrificial material (262). In this manner, the capping layer (140) and ILD layer (130) are etched at a significantly greater rate than the sacrificial material (262) such that the sacrificial material (262) above capping layer (140) acts as an etch mask after the hard mask layer (282) is etched away, and such that the sacrificial material (262a) in the bottom of the via hole (150) is not over etched, thereby protecting the etch stop layer (120) and lower interconnection line (110) from exposure to the etching atmosphere. For example, as depicted in FIG. 16, a relatively small amount of sacrificial material (262b) is etched away during this etch process (327). In one exemplary embodiment, the etch process (327) is performed using a dry etch process with etching gases CxFyHz/CO/O2/N2/Ar.

Referring to FIG. 16, as with the exemplary method steps described above with reference to FIG. 7, a process is performed to remove the porogen material from the remaining sacrificial material (262, 262a) to convert the sacrificial material (262, 262a) to a porous matrix material (262′, 262a′). In particular, the sacrificial material (262, 262a) is transformed to a porous matrix material (262′, 262a′) by decomposing the pockets/regions of porogen material, which is dispersed throughout the base matrix material, to thereby create pores or voids in the matrix material. In this manner, the sacrificial material is converted to a porous matrix material, wherein the matrix is a solid phase surrounding dispersed voids/pores.

As noted above, the porogen material can be removed from the sacrificial material by heating the sacrificial material to a temperature above a boiling point of the porogen material to dissolve the porogen material from the base material. The heating is performed for about 1 minute to about 2 hours. The heating is performed in a vacuum or nitrogen environment. In one exemplary embodiment, the boiling point of the porogen material is in a range of about 150 degrees C. to about less than 400 degrees C. In another embodiment, UV radiation can be applied to the sacrificial material while heating the sacrificial material to assist in removal of the porogen material. In another exemplary embodiment of the invention, removing the porogen material may be performed using a plasma treatment process to dissolve the porogen material from the base material. The plasma treatment is performed using a nitrogen-based plasma or hydrogen-based plasma.

Advantageously, the porous sacrificial material (262a′) in the via hole maintains its structural integrity (the matrix base material maintains its structure) but is porous. Therefore, the porous material (262a′) in the via hole (150) does not add stress to sidewall surfaces of the ILD layer in the via hole (150) (e.g., stress due to shrinkage as in the conventional process). Moreover, the porous structure effectively increases the surface area of the sacrificial material enabling the porous material (262′, 262a′) to be more easily removed, thus significantly minimizing damage to the ILD layer when removing the porous material (262a′) in the via hole (150).

Next, referring to FIG. 17, the remaining porous sacrificial material (262′, 262a′) is removed to expose the etch stop layer (120) in the via hole (150). The porous sacrificial material can be readily removed one of various methods. For example, when the porous sacrificial material (262′, 262a′) comprises an organic base material and the ILD layer (130) is formed of an inorganic material, the porous sacrificial material (262′, 262a′) can be removed using any suitable etch process (e.g., a wet strip process) having an etch chemistry that is selected to provide high selectivity between the base material of the porous sacrificial material (262′, 262a′)) and the material of the ILD layer (130). Again, due to the existence of the pores in the base material, the etch process results in removing the sacrificial material 2-4 times faster than removal of the same, non-porous base material because the etch solution/gas can readily penetrate into the porous base material. In other words, the existence of the pores in the base material effectively increases the surface area of the sacrificial material to which the etch solution/gas can be applied. The increased etch rate of the porous sacrificial material allows fast and efficient removal of the porous sacrificial material to minimize or otherwise prevent damage to the ILD layer (130).

After removing the remaining porous sacrificial material (262′, 262a′), the next step of the exemplary method includes removing the portion of the etch stop layer (120) that is exposed on the bottom of the via hole (150) to expose the lower conductive layer (110). This etch process may be performed using known techniques to selectively etch the material forming the etch stop layer (120) without etching the ILD layer (130). The resulting structure is depicted in the exemplary diagram of FIG. 17.

Thereafter, referring to FIG. 18, an upper metal interconnection (330) (dual damascene interconnection) is formed by filling the entire region (295) comprising the trench (190) and via hole (150) with conductive material such as copper. More specifically, in one exemplary embodiment, a method of forming the upper interconnection structure (230) includes forming a conformal barrier layer (300) on the sidewalls of the trench (190) and via hole (150). In one exemplary embodiment, the barrier layer (300) may be formed using a sputter deposition process to form a barrier layer of thickness of about 50 angstroms to about 500 angstroms with a material such as TiN or TaN, for example. Thereafter, a layer of conductive material is deposited over the conformal barrier layer (300) to fill the via hole (150) and trench (190) with the conductive material, and then a planarization (e.g., CMP) process is performed to planarize the top surface of the structure down to the hard mask layer (140), thus completing formation of a metal wiring layer having a dual damascene structure (330).

Although exemplary embodiments have been described herein with reference to the accompanying drawings, it is to be understood that the invention is not limited to the exemplary embodiments described herein, and that various other changes and modifications may be readily envisioned by one of ordinary skill in the art without departing form the scope or spirit of the invention. All such changes and modifications are intended to be included within the scope of the invention as defined by the appended claims.

We claim:

1. A method for forming an interconnection structure, comprising:
forming an etch stop layer on a semiconductor substrate that has a lower conductive layer formed thereon;
forming an ILD (interlayer dielectric) layer on the etch stop layer;
forming a via hole through the ILD layer to expose a portion of the etch stop layer, the via hole being aligned with a portion of the lower conductive layer;
filling the via hole with a sacrificial material comprising a combination of a base material and a porogen material;
forming a trench in the ILD layer aligned with the via hole;
removing the porogen material from the sacrificial material to convert the sacrificial material to a porous sacrificial material comprising the base material with pores formed therein;
removing the porous sacrificial material in the via hole to expose a portion of the etch stop layer;
removing the exposed portion of the etch stop layer; and
forming an interconnection by filling the trench and via hole with a conductive material.

2. The method of claim 1, wherein removing the porous sacrificial material is performed using a wet strip process.

3. The method of claim 1, wherein removing the porous sacrificial material is performed using an ashing process.

4. The method of claim 1, wherein removing the porogen material from the sacrificial material comprises heating the sacrificial material to a temperature above a boiling point of the porogen material to dissolve the porogen material from the base material.

5. The method of claim 4, wherein heating is performed in a range of about 1 minute to about 2 hours.

6. The method of claim 4, wherein heating is performed in a vacuum or nitrogen environment.

7. The method of claim 4, wherein the boiling point of the porogen material is in a range of about 150 degrees C. to about less than 400 degrees C.

8. The method of claim 4, further comprising applying UV radiation to the sacrificial material while heating the sacrificial material.

9. The method of claim 1, wherein removing the porogen material comprises applying a plasma treatment to dissolve the porogen material from the base material.

10. The method of claim 9, wherein the plasma treatment is performed using a nitrogen-based plasma or hydrogen-based plasma.

11. The method of claim 1, wherein the base material of the sacrificial material comprises an organic material.

12. The method of claim 11, wherein the organic material is an SOP (spin-on-polymer) material.

13. The method of claim 12, wherein the SOP material comprises a poly arylene ether-based material, a polymetamethylacrylate-based material, or a vinylethermetacrylate-based material.

14. The method of claim 1, wherein the base material of the sacrificial material comprises an inorganic material.

15. The method of claim 14, wherein the inorganic material is an SOG (spin-on-glass) material.

16. The method of claim 15, wherein the SOG material comprises an HSQ (hydrogenSilsesQuioxane)-based material or an MSQ (MethylSilsesQuioxane)-based material.

17. The method of claim 1, wherein the sacrificial material comprises the porogen material in an amount of about 1 wt % to about 70 wt % of a total weight of the sacrificial material.

18. The method of claim 1, further comprising forming a capping layer on the ILD layer.

19. The method of claim 1, wherein forming the interconnection comprises:
forming a conformal barrier layer on the trench and via sidewalls and the exposed portion of the lower conductive layer;
depositing a layer of conductive material over the conformal barrier layer to fill the via hole and trench with the conductive material; and
planarizing the layer of conductive material.

20. The method of claim 1, wherein forming the via hole comprises:
forming an AR (anti-reflection) layer;
forming a photoresist pattern on the AR layer;
forming the via hole by etching the AR layer and the ILD layer using the photoresist pattern as an etch mask; and
removing the photoresist pattern and the AR layer.

21. The method of claim 1, wherein forming the trench comprises:
forming an AR (anti-reflection) layer;
forming a photoresist pattern on the AR layer; and
forming the trench by etching the AR layer, the sacrificial material and the ILD layer using the photoresist pattern as an etch mask.

22. The method of claim 1, wherein forming the trench comprises:
forming a hard mask pattern;
removing sacrificial material exposed by the hard mask pattern down to about at least a predetermined trench level below a surface of the ILD layer;
forming the trench by etching the ILD layer down to the predetermined trench level, using the hard mask pattern as an etch mask; and
removing the hard mask pattern.

23. The method of claim 22, wherein forming the hard mask pattern comprises:
forming a hard mask layer;
forming an AR (anti-reflection) layer on the hard mask layer;
forming a photoresist pattern on the AR layer; and
forming the hard mask pattern by etching the AR layer and the hard mask layer using the photoresist pattern as a mask.

24. The method of claim 22, further comprising removing the photoresist pattern and the AR layer while removing sacrificial material exposed by the hard mask pattern.

25. The method of claim 22, wherein removing the hard mask pattern is performed while etching the ILD layer to form the trench.

26. The method of claim 23, wherein the hard mask layer comprises one of a silicon oxide layer, a silicon nitride layer, a silicon carbide layer, SiON, SiCN, SiOCN, Ta, TaN, Ti, TiN, Al2o3, BQ, HSQ, or a material that has a high etching selectivity with respect to the sacrificial material.

27. The method of claim 1, wherein the etch stop layer is formed of a silicon nitride, a silicon carbide, SiCN, or a combination thereof, and has an etching selectivity with respect to the ILD layer.

28. The method of claim 1, wherein the ILD layer comprises a low-k dielectric material, wherein k is less than about 4.2.

29. The method of claim 28, wherein the ILD layer is formed of an organic material.

30. The method of claim 28, wherein the ILD layer is formed of an inorganic material.

31. A method for forming a semiconductor device, comprising:
forming a via hole in a dielectric layer on a semiconductor substrate;
filling the via hole with a sacrificial material comprising a combination of a base material and a porogen material;
removing the porogen material from the sacrificial material to convert the sacrificial material to a porous sacrificial material comprising the base material with pores formed therein; and
removing the porous sacrificial material in the via hole.

32. The method of claim 31, wherein the base material of the sacrificial material comprises an organic material.

33. The method of claim 32, wherein the organic material is an SOP (spin-on-polymer) material.

34. The method of claim 33, wherein the SOP material comprises a poly arylene ether-based material, a polymetamethylacrylate-based material, or a vinylethermetacrylate-based material.

35. The method of claim 31, wherein the base material of the sacrificial material comprises an inorganic material.

36. The method of claim 35, wherein the inorganic material is an SOG (spin-on-glass) material.

37. The method of claim 36, wherein the SOG material comprises an HSQ (hydrogenSilsesQuioxane)-based material or an MSQ (MethylSilsesQuioxane)-based material.

38. The method of claim 31, wherein the sacrificial material comprises the porogen material in an amount of about 1 wt % to about 70 wt % of a total weight of the sacrificial material.

39. The method of claim 31, wherein removing the porous sacrificial material is performed using a wet strip process.

40. The method of claim 31, wherein removing the porous sacrificial material is performed using an ashing process.

41. The method of claim 31, wherein removing the porogen material from the sacrificial material comprises heating the sacrificial material to a temperature above a boiling point of the porogen material to dissolve the porogen material from the base material.

42. The method of claim 41, wherein heating is performed in a range of about 1 minute to about 2 hours.

43. The method of claim 41, wherein heating is performed in a vacuum or nitrogen environment.

44. The method of claim 41, wherein the boiling point of the porogen material is in a range of about 150 degrees C. to about less than 400 degrees C.

45. The method of claim 41, further comprising applying UV radiation to the sacrificial material while heating the sacrificial material.

46. The method of claim 31, wherein removing the porogen material comprises applying a plasma treatment to dissolve the porogen material from the base material.

47. The method of claim 46, wherein the plasma treatment is performed using a nitrogen-based plasma or hydrogen-based plasma.

48. The method of claim 31, wherein the dielectric layer comprises a low-k dielectric material, wherein k is less than about 4.2.

49. The method of claim 31, wherein the method is performed for constructing a dual damascene interconnection.

50. A method for forming a semiconductor device, comprising:
forming a lower conductive layer on a semiconductor substrate; and
forming a dual damascene interconnection that electrically connects to a contact portion of the lower conductive layer,
wherein forming the dual damascene interconnection comprises:
forming a via hole in a dielectric layer, wherein the via hole is aligned with the contact portion of the lower conductive layer;
filling the via hole with a sacrificial material comprising a combination of a base material and a porogen material;
removing the porogen material from the sacrificial material to convert the sacrificial material to a porous sacrificial material comprising the base material with pores formed therein; and
removing the porous sacrificial material in the via hole; and
filling the via hole with conductive material.

51. The method of claim 50, wherein forming the dual damascene interconnection is performed using a via first dual damascene (VFDD) process.
